(19) United States
(12) Patent Application Publication
(10) Pub. No.: US 2017/0205706 A1
(43) Pub. Date: Jul. 20, 2017

(54) A Suspended Structure Made of Inorganic Materials and a Method for Manufacturing Same

(71) Applicant: PLANXWELL LTD., GANEY TIKVA (IL)

(72) Inventors: David BEN-BASSAT, Ganey Tikva (IL); Tal HAVDALA, Tel Aviv (IL)

(21) Appl. No.: 15/324,054

(22) PCT Filed: Jun. 25, 2015
(86) PCT No.: PCT/IL2015/000033

§ 371 Date: Jan. 5, 2017

Related U.S. Application Data
(60) Provisional application No. 62/021,238, filed on Jul. 7, 2014.

(51) Int. Cl. G03F 7/00; G03F 7/30; G03F 7/40; B81C 1/00

(52) U.S. Cl. CPC G03F 7/0002; B81C 1/00396; G03F 7/30; G03F 7/40

(57) ABSTRACT

A device and a method for manufacturing it are disclosed wherein the devices comprises a substrate and at least a first layer and a second layer that are partially etched, all made of inorganic materials, and wherein the at least partially etched first layer and the at least partially etched second layer form together a suspended structure, and wherein each of the first layer and the second layer has a different pre-determined shape from the other.

### TECHNICAL FIELD

The present disclosure generally relates to methods of manufacturing microelectronic devices, and more particularly, to the use of masks in manufacturing microelectronic devices.

### BACKGROUND

Lithography masks are commonly used in processes of manufacturing microelectronic devices as means to imprint patterns onto respective substrates. Typically, optical resist materials are used to incorporate the masks at the target substrate.

There are certain cases where bi-layer suspended masks are used. Bi-layer suspended masks are two-level structures, where the upper level contains the pattern to be imprinted, while the lower level serves as a sacrificial layer. In these structures, the lower layer sometimes serves as a support layer for the top layer. The lower layer supports the upper layer with undercut structures, thus allowing the upper layer to define the overall geometry.

Currently, the standard practice of generating a bi-layer suspended mask requires the use of optical resist materials. A typical such process comprises the following steps:
(i) Providing a substrate onto which the mask shall be constructed;
(ii) Placing a first layer of resist (referred to herein as a sacrificial layer) so as to coat the substrate provided. Typically, the resist materials are liquid polymer resins, and as such, the most suitable way to apply them onto the substrate is by using a technique known as spin coating, although other coating techniques are also applicable;
(iii) After carrying out step (ii) of spin coating the substrate with resist material, the coated substrate undergoes a baking step in which the substrate with its resist coating are placed on a hot plate (or in an oven);
(iv) Next, a second layer of resist is applied for coating the substrate. The resist used in this stage is chemically different from the resist used in step (ii). The resist layer formed in this step is referred to as a top layer. Here, again, spin coating is a typical way to apply the resist onto the substrate;
(v) Following the second spin coating step, the substrate with the two coating layers undergo a second baking step at which the temperature is typically lower than the temperature at which the first baking step was carried out, thus, the lower layer resist (also referred to as sacrificial layer resist) is not impacted by the second baking;
(vi) The product of step (v) is then subjected to irradiation so that the radiation which is not blocked by an optical mask reaches the substrate, thereby projecting the required pattern onto the substrate. The top resist layer is typically a polymer that is chemically sensitive to the arriving radiation, therefore areas which are exposed to the radiation change their chemical properties;
(vii) The substrate is then immersed in a developing solution, so that the active agent of the solution interacts with areas of the top layer resist that were chemically changed, and dissolves these areas;
(viii) Finally, the lower resist layer is etched by immersing the three layered device in a selective etching agent (adapted to dissolve the bottom resist but without interacting with either the top resist or the substrate). In order to maintain a suspended mask, the lower resist is not fully developed and is only partially etched away.

FIG. 1 is a schematic illustration of a cross section of a product resulting from the above described prior art process. Assuming that the lower resist was etched properly, a mask made of the top resist is being held suspended over the substrate.

Such suspended masks made of resists serve for many purposes in the fields of micro fabrication, nano imprinting and Micro Electro Mechanical Systems (MEMS). In some cases, the use of oxygen plasma may be required as part of the process. Oxygen plasma is usually used in combination with various metals, where there is a need for in-situ generation of oxides. For example, such a typical process would be a Physical Vapor Deposition (PVD) of metal, while using controlled oxygen plasma in the chamber. As the metal vapors pass through the plasma, they will bond with the oxygen ions to create metal oxide molecules.

Unfortunately, most resist materials are chemically reactive to oxygen plasma. Consequentially, the in-situ use of oxygen plasma might yield some adverse effects on the process, namely:
(a) The resists might discharge materials (e.g. gases) that will damage the purity of the process; and
(b) In extreme cases, the resists might even be converted into ash and then disappear in a process that may be considered similar to a burning process.

### SUMMARY OF THE DISCLOSURE

The disclosure may be summarized by referring to the appended claims.

It is an object of the present disclosure to provide a device that comprises a suspended mask made of only inorganic materials and a method for producing that device.

It is yet another object of the present disclosure to provide a device comprising a substrate and two inorganic layers that comprises a suspended mask etched in both layers.

It is still another object of the present invention to provide a suspended structure (mask) made of materials that are agnostic to plasma-based processes and in particularly oxygen plasma, hence may be used in plasma-based processes.

Other objects of the present invention will become apparent from the following description.

According to one embodiment of the disclosure, there is provided a device comprising a substrate and at least a first layer and a second layer that are partially etched, all made of inorganic materials, and wherein the at least partially etched first layer and the at least partially etched second layer form together a suspended structure, and wherein each of the first layer and the second layer has a different pre-determined shape from the other, (e.g., the second layer has various undercuts with respect to the first layer).

In accordance with another embodiment, the inorganic materials are selected from a group that consists of oxides, metals and ceramic materials.

By yet another embodiment the first layer comprises Aluminum (e.g. in the form of Aluminum Nitrite).

According to still another embodiment, the second layer comprises Germanium or Niobium.

In accordance with another embodiment the device is characterized as being adapted for use in a plasma-based material processing technology that aims at modifying the chemical and physical properties of a surface, e.g. for oxygen plasma processing. Preferably, the device is plasma agnostic so that it is durable under plasma conditions.

According to another aspect of the present disclosure, there is provided a method for manufacturing a bi-layer suspended structure, which comprises the steps of:
(i) providing a substrate layer;
(ii) carrying out a Physical Vapor Deposition (PVD) of a first layer on a substrate layer wherein thea first layer comprises a first inorganic material;
(iii) carrying out a Physical Vapor Deposition (PVD) of a second layer on top of the first layer, wherein said second layer comprises a second inorganic material;
(iv) depositing resist layer on top of the second layer;
(v) exposing the layered structure to radiation while using a radiation-selective mask, to chemically react with pre-determined resist areas of the resist layer;
(vi) immersing the layered structure in a liquid developing agent, wherein the developing agent is adapted to react with (e.g. dissolve) the areas of the resist layer that were exposed to radiation;
(vii) applying an etching agent adapted to selectively etch the inorganic material comprised in the second layer, while refraining from attacking the material comprised in the first layer;
(viii) removing the remains of the resist layer still located on top of the etched second layer; and
(ix) etching the first layer by using a selective etching agent adapted to selectively react with the inorganic material comprised in the first layer but agnostic to the material comprised in the substrate layer and the inorganic material comprised in the second layer, wherein the etching of the first layer is carried out so that one or more of the non-etched parts of the first layer are smaller than respective non-etched parts of the second layer which are located on top of the one or more non-etched parts of the first layer.

According to another embodiment the method further comprises a step of selecting one of the first and second materials to be a material that is chemically reactive to a pre-determined etching agent, whereas the other of the first and second materials is a material that is chemically non-reactive to the pre-determined etching agent.

The term “resist” as used herein throughout the specification and claims is used to denote a thin layer used to transfer a circuit pattern to a layer which it is deposited thereupon. A resist can be patterned via lithography to form a (sub)micrometer-scale, temporary mask that protects selected areas of the underlying layer during subsequent processing steps. The material used to prepare this thin layer is typically a viscous solution. Resists are generally proprietary mixtures of a polymer or its precursor and other small molecules (e.g. photoacid generators) that have been specially formulated for a given irradiation technology (such as lithography).

The term “suspended structure” as used herein throughout the specification and claims is used to denote a configuration (a bi- or multi-layered structure) prepared by etching differently various layers to receive that structure, and is characterized in that a certain layer comprises non-etched areas which are greater than non-etched areas comprised in an adjacent lower layer, located directly beneath the respective areas comprised in the upper layer.

### BRIEF DESCRIPTION OF THE DRAWING

For a more complete understanding of the present invention, reference is now made to the following detailed description taken in conjunction with the accompanying drawing wherein:

FIG. 1—is a schematic illustration of a cross section of a product that resulted from a prior art process;

FIG. 2—is a flow chart demonstrating a method for carrying out an embodiment of the present invention;

FIG. 3—is a schematic illustration of a cross section of one possible interim product after step 230 of the method demonstrated in FIG. 2 has been carried out;

FIG. 4—is a schematic illustration of one possible cross section of an interim product after step 260 of the method demonstrated in FIG. 2 has been carried out;

FIG. 5—is a schematic illustration of a cross section of one possible interim product after step 270 of the method demonstrated in FIG. 2 has been carried out; and

FIG. 6—is a schematic illustration of a cross section of one possible interim product after the method demonstrated in FIG. 2 has been carried out.

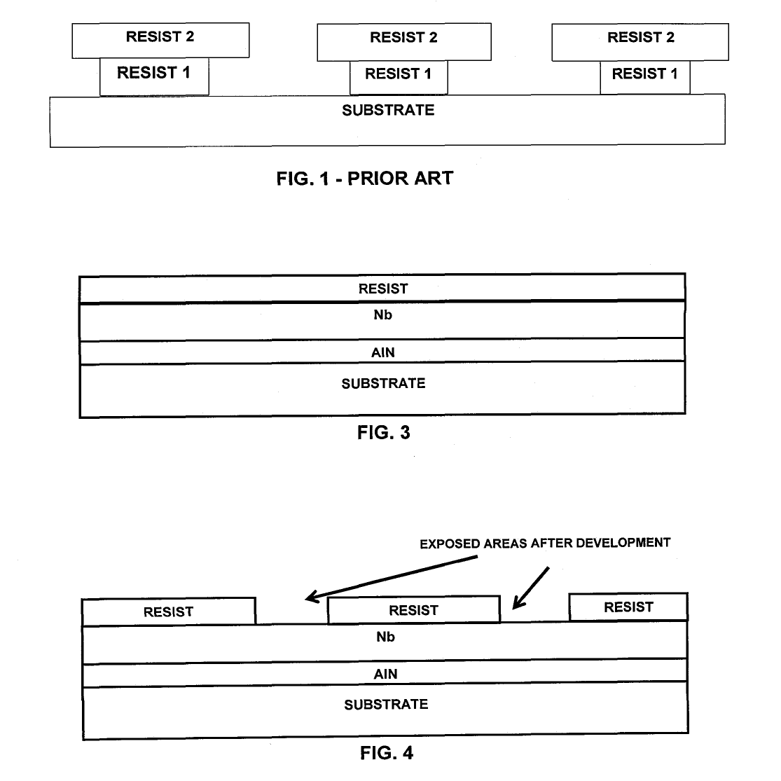

### DETAILED DESCRIPTION

In this disclosure, the term “comprising” is intended to have an open-ended meaning so that when a first element is stated as comprising a second element, the first element may also include one or more other elements that are not necessarily identified or described herein, or recited in the claims.

In the following description, for the purposes of explanation, numerous specific details are set forth in order to provide a better understanding of the present invention by way of examples. It should be apparent, however, that the present invention may be practiced without these specific details.

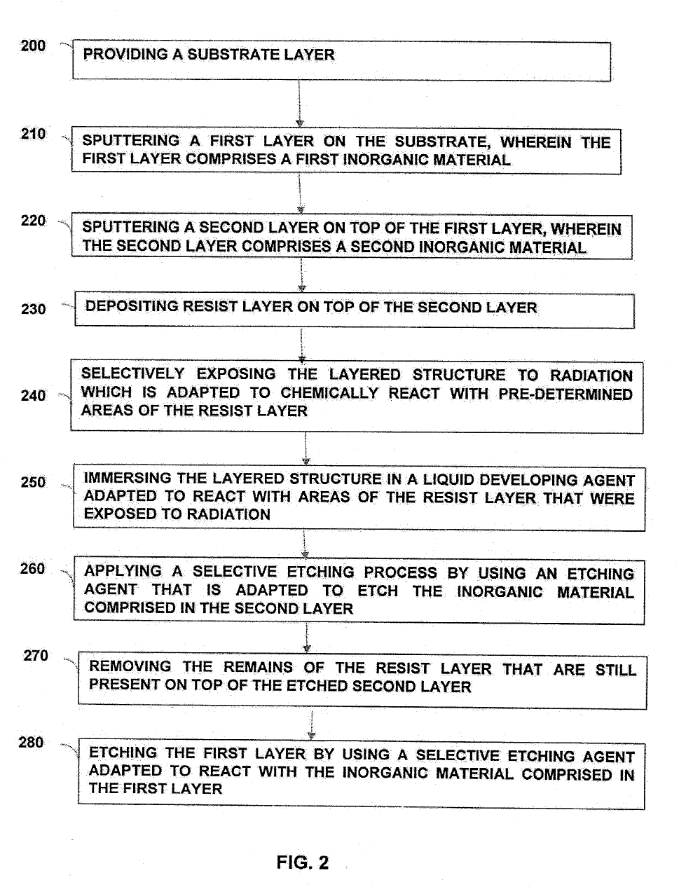

According to one aspect of the present disclosure there is provided a method for manufacturing a bi-layer suspended structure. FIG. 2 is a flow chart of an example demonstrating such a process that comprises the following steps:

The process begins by providing a substrate layer (step 200) and carrying out a Physical Vapor Deposition (PVD) of a first layer onto that substrate layer. The material used for this step is a metallic salt such as for example Aluminum nitrite (AlN) which is deposited onto the substrate to form a first coating layer by applying a Physical Vapor Deposition of the metallic salt onto the substrate (step 210).

Next, a second layer which comprises a different material from the one used for the first layer, is sputtered onto the first layer by applying once again a Physical Vapor Deposition process (step 220). A sputter of Niobium (Nb) may be considered as an example for this second layer.

As will be appreciated by those skilled in the art, although the first two steps if this example are described as two separate steps, still, they may both be carried out in-situ, without having to open the sputter chamber between these two steps.

In the following step (step 230), a resist layer is deposited on the second layer (the Niobium layer of this example). The resist material may be one that is sensitive to electron beam (e-beam resist), visible light radiation (photolithography resist), or any other applicable resists that are known in the art per se. One possible way of applying the resist to form the resist layer is by carrying out a spin coating procedure. FIG. 3 illustrates the product received after carrying out step 230.

Following the deposition of the resist layer, the four layered combination is preferably (but not necessarily) baked, for example by placing it over a hot plate or in an oven.

Then, the layered device is subjected selectively to the appropriate radiation (step 240), depending on the type of the resist used (i.e. the resist layer will be exposed to a radiation of the type that will invoke a chemical reaction at certain areas thereat that will be exposed to that radiation), thereby forming a required pattern that comprises areas that were exposed to the radiation and areas that were not exposed to that radiation.

Next, the layered device is immersed in a liquid agent (a developing agent) which reacts with the resist's areas that were exposed to radiation (the areas that were chemically altered due to their exposure to the radiation) and dissolves these areas (step 250).

FIG. 4 is a schematic illustration of a cross section of the coated substrate, after step 250 has been carried out. As can be seen from this FIG., the areas that had been exposed to radiation and then developed, are missing from the resist layer.

In step 260 the layered device undergoes a Reactive Ion Etching (“RIE”) process, which enables a selective etching process in which the second layer (the Niobium layer of this example) is being etched, while the first layer (the Aluminum Nitrite layer) is not affected by the etching agent. In this process, the parts that are not masked by the remains of the resist layer will be etched away, whereas the areas covered by the leftovers of the resist layer, will remain intact.

FIG. 5 is a schematic illustration of a cross section of the coated substrate, after carrying out step 260. As may be seen from this FIG., certain areas of the top layer (underneath the remaining areas of the resist layer), are missing from that layer (the Nb layer of this example).

Next, the remains of the resist layer are removed, preferably, by immersing the layered device in a solvent such as acetone or the like (step 270).

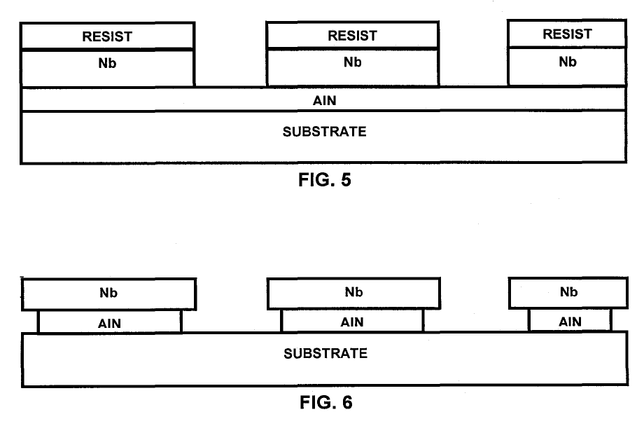

The following step (step 280) is a wet etching of the lower layer (the AlN of the present example). In this step the sample is immersed in a liquid which serves as a selective etching agent which is adapted to react with the material comprising the lower layer (the AlN) but not the substrate or the material comprising the top layer (the Nb). The etching agent fills the gaps that exist at the second (top) layer and begins etching the first (lower) layer. First etching is done downwardly through the first layer, and then etching of the first lower is done in the horizontal direction, thereby forming a suspended structure as illustrated in FIG. 6. The etching of the first layer is preferably time controlled, so that by removing the etching agent after a pre-determined period of time, the desired suspended structure is formed.

The device thus formed is an inorganic suspended mask that is made only of inorganic materials such as oxides, ceramic materials and/or metal layers. As both oxides and metal are materials which are agnostic to oxygen plasma (as well as other types of plasma), they maintain their properties (i.e. the suspended structure shape of the device) when incorporated in processes where they are subjected to such a plasma, without being deformed or subjected to a chemical reaction.

In the description and claims of the present application, each of the verbs, “comprise” “include” and “have”, and conjugates thereof, are used to indicate that the object or objects of the verb are not necessarily a complete listing of members, components, elements or parts of the subject or subjects of the verb.

The present invention has been described using descriptions of embodiments thereof that are provided by way of example and are not intended to limit the scope of the invention in any way. The described embodiments comprise different features, not all of which are required in all embodiments of the invention. Some embodiments of the present invention utilize only some of the features or possible combinations of the features. Variations of embodiments of the present invention that are described and embodiments of the present invention comprising different combinations of features noted in the described embodiments will occur to persons of the art. The scope of the invention is limited only by the following claims.

1. A device comprising a substrate and at least a first layer and a second layer that are partially etched, all made of inorganic materials, and wherein the at least partially etched first layer and the at least partially etched second layer form together a suspended structure, and wherein each of the first layer and the second layer has a different pre-determined shape from the other.

2. The device according to claim 1, wherein the inorganic materials are selected from a group that consists of oxides, metals and ceramic materials.

3. The device according to claim 1, wherein the first layer comprises Aluminum or Aluminum Nitrite.

4. The device according to claim 1, wherein the second layer comprises Germanium or Niobium.

5. The device according to claim 1, characterized in being adapted for use in a plasma-based material processing technology.

6. A method for manufacturing a bi-layer suspended structure, comprising the steps of:
(i) providing a substrate layer;
(ii) carrying out a Physical Vapor Deposition of a first layer on the substrate layer wherein said first layer comprises a first inorganic material;
(iii) carrying out a Physical Vapor Deposition of a second layer on top of the first layer, wherein said second layer comprises a second inorganic material;
(iv) depositing resist layer on top of the second layer;
(v) exposing the layered structure to radiation while using a radiation-selective mask, to chemically react with pre-determined resist areas of the resist layer;
(vi) immersing the layered structure in a liquid developing agent, wherein the developing agent is adapted to react with the areas of the resist layer that were exposed to radiation;
(vii) applying an etching process by using an etching agent adapted to selectively etch the inorganic material comprised in the second layer while refraining from reacting with said first layer;
(viii) removing remains of the resist layer still located on top of the etched second layer; and
(ix) etching the first layer by using a selective etching agent adapted to selectively react with the inorganic material comprised in the first layer but agnostic to the material comprised in the substrate layer and the inorganic material comprised in the second layer, wherein the etching of the first layer is carried out so that one or more of the non-etched parts of the first layer are smaller than respective non-etched parts of the second layer which are located on top of that one or more of the non-etched parts of the first layer.

7. The method of claim 6, further comprising a step of selecting one of the first and second materials to be a material that is chemically reactive to a pre-determined etching agent, and whereas the other of the first and second materials is a material that is chemically non-reactive to the pre-determined etching agent.
